(19) United States
(12) Patent Application Publication
(10) Pub. No.: US 2025/0293110 A1
(43) Pub. Date: Sep. 18, 2025

(54) SEMICONDUCTOR MODULE AND POWER CONVERSION UNIT

(71) Applicant: Rohm Co., Ltd., Kyoto-shi (JP)

(72) Inventors: Hirokatsu UMEGAMI, Kyoto-shi (JP); Takukazu OTSUKA, Kyoto-shi (JP)

(21) Appl. No.: 19/225,423

(22) Filed: Jun. 2, 2025

Related U.S. Application Data
(63) Continuation of application No. PCT/JP2023/042160, filed on Nov. 24, 2023.

(30) Foreign Application Priority Data
Dec. 8, 2022 (JP) 2022-196259

(51) Int. Cl. H01L 23/36; H01L 23/31; H01L 23/473; H01L 23/495

(52) U.S. Cl. CPC H01L 23/36; H01L 23/3107; H01L 23/473; H01L 23/49517

(57) ABSTRACT

A semiconductor module may include a semiconductor device and a heat dissipation member. The semiconductor device may include a substrate, a semiconductor element mounted on the substrate, and a sealing resin covering the semiconductor element. The substrate may be exposed from the sealing resin. The heat dissipation member may include a first support surface and a second support surface facing away from each other in a first direction. The substrate may be supported on the first support surface.

### TECHNICAL FIELD

The present disclosure relates to a semiconductor module including a semiconductor device and a heat dissipation member, and a power conversion unit including the semiconductor module.

### BACKGROUND ART

WO 2017/094370 discloses an example of a semiconductor module including a semiconductor device and a cooler. The cooler includes a housing having a hollow region, and a heat dissipator. The housing has an opening connected to the hollow region. The heat dissipator is attached to the housing to close the opening. A portion of the heat dissipator is housed in the hollow region. The semiconductor device is bonded to a portion of the heat dissipator that extends outward from the hollow region. When a coolant (such as cooling water) flows into the hollow region, the coolant comes into contact with the heat dissipator. In this way, the semiconductor device is cooled efficiently through the heat dissipator.

In the configuration of the semiconductor module disclosed in WO 2017/094370, the cooler is relatively large in scale. Thus, a considerable amount of space is required to dispose the semiconductor module. It is therefore desired to provide a semiconductor module that can be disposed in a smaller space.

### BRIEF DESCRIPTION OF THE DRAWINGS

FIG. 1 is a plan view of a semiconductor module and a power conversion unit according to a first embodiment of the present disclosure.

FIG. 2 is a right side view of the semiconductor module and the power conversion unit shown in FIG. 1.

FIG. 3 is a rear view of the semiconductor module and the power conversion unit shown in FIG. 1.

FIG. 4 is a sectional view taken along line IV-IV in FIG. 1.

FIG. 5 is a sectional view taken along line V-V in FIG. 1.

FIG. 6 is a partial enlarged view of FIG. 5.

FIG. 7A is a plan view of the semiconductor device included in the semiconductor module shown in FIG. 1.

FIG. 7B is a plan view of an additional semiconductor device included in the semiconductor module shown in FIG. 1.

FIG. 8 is a bottom view of the semiconductor device shown in FIG. 7A.

FIG. 9A is a front view of the semiconductor device shown in FIG. 7A.

FIG. 9B is a front view of the additional semiconductor device shown in FIG. 7B.

FIG. 10 is a left side view of the semiconductor device shown in FIG. 7A.

FIG. 11 is a circuit diagram of each of the semiconductor device shown in FIG. 7A and the additional semiconductor device shown in FIG. 7B.

FIG. 12 is a plan view of a semiconductor module and a power conversion unit according to a second embodiment of the present disclosure.

FIG. 13 is a right side view of the semiconductor module and the power conversion unit shown in FIG. 12.

FIG. 14 is a rear view of the semiconductor module and power conversion unit shown in FIG. 12.

FIG. 15 is a sectional view taken along line XV-XV in FIG. 12.

FIG. 16 is a partial enlarged view of FIG. 15.

FIG. 17 is a plan view of a semiconductor module and a power conversion unit according to a third embodiment of the present disclosure.

FIG. 18 is a right side view of the semiconductor module and the power conversion unit shown in FIG. 17.

FIG. 19 is a rear view of the semiconductor module and the power conversion unit shown in FIG. 17.

FIG. 20 is a plan view of a semiconductor module and a power conversion unit according to a fourth embodiment of the present disclosure.

FIG. 21 is a sectional view taken along line XXI-XXI in FIG. 20.

### DETAILED DESCRIPTION OF EMBODIMENTS

Modes for carrying out the present disclosure will be described with reference to the accompanying drawings.

### First Embodiment

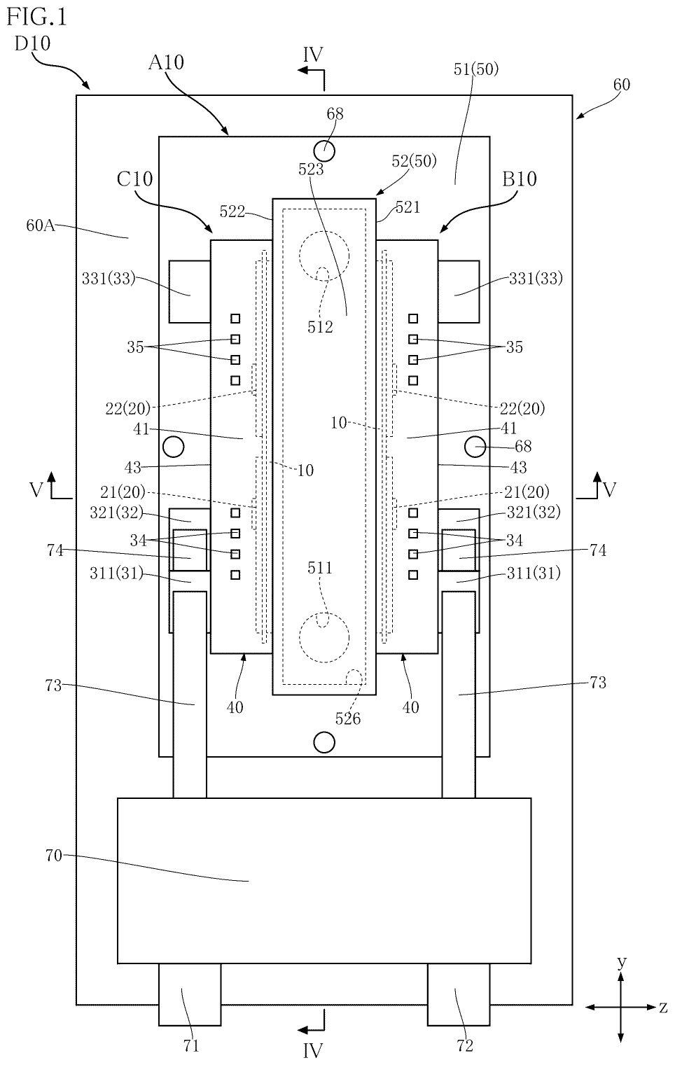

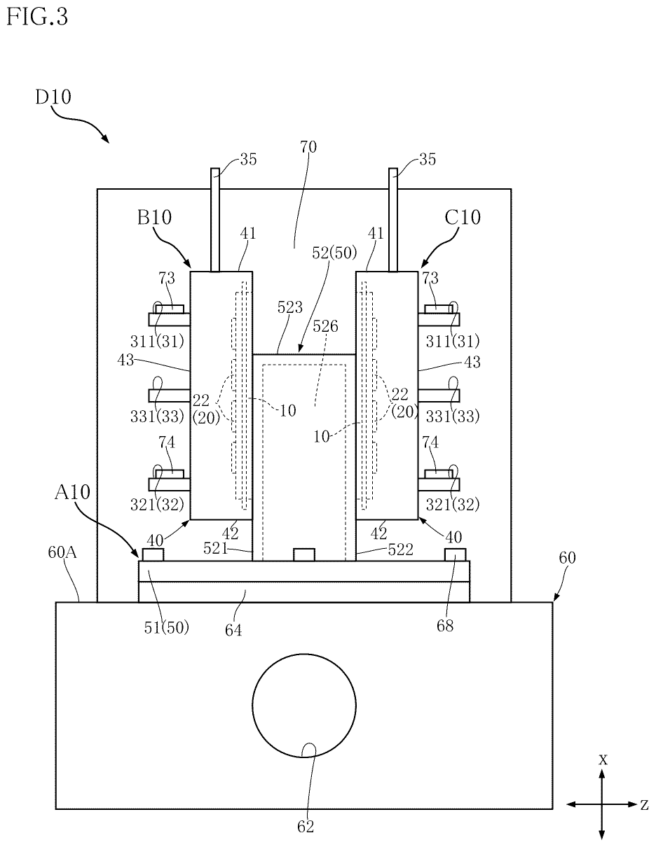

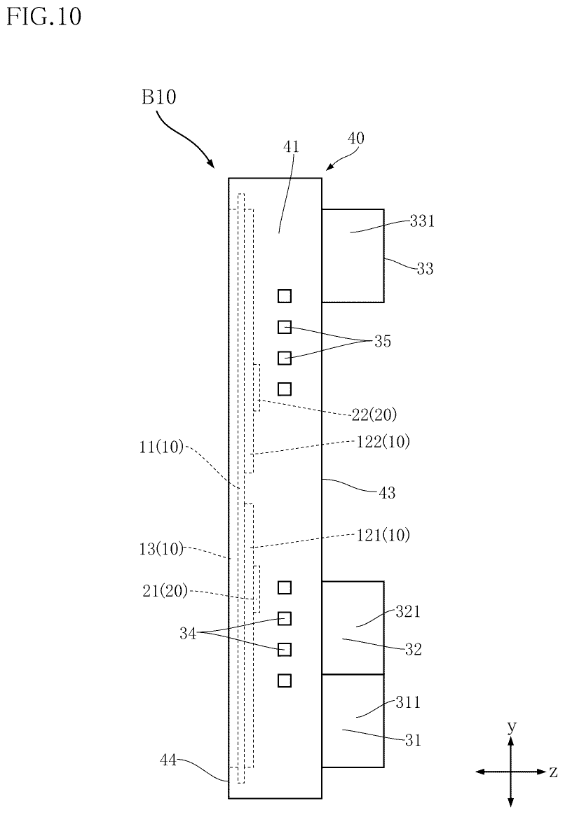

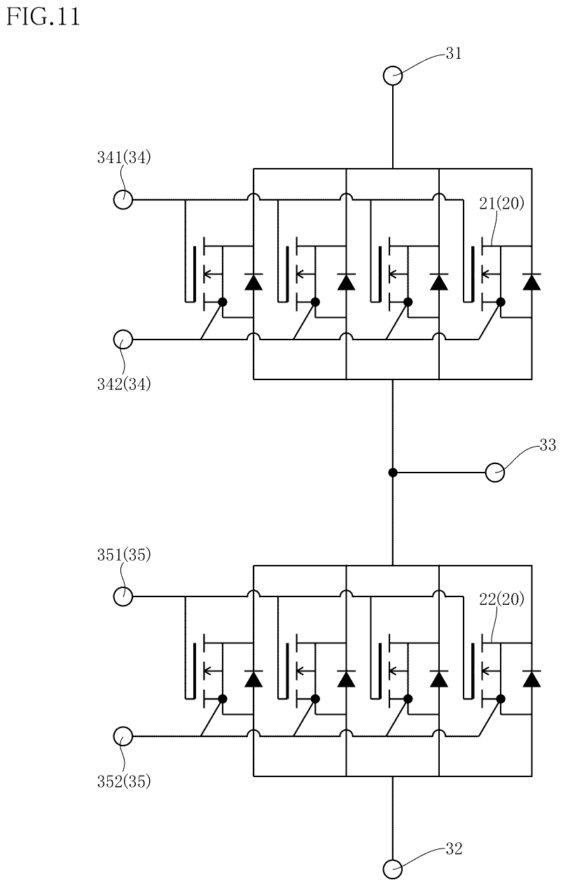

A semiconductor module A10 and a power conversion unit D10 according to a first embodiment of the present disclosure will be described based on FIGS. 1 to 11. The semiconductor module A10 may include a semiconductor device B10, an additional semiconductor device C10, and a heat dissipation member 50. The power conversion unit D10 may include the semiconductor module A10, a cooler 60, and a capacitor 70.

In the description of the semiconductor module A10 and the power conversion unit D10, the direction that is normal to the third surface 43 of the sealing resin 40 of the semiconductor device B10, which will be described later, is referred to as the “first direction z” for the convenience. A direction orthogonal to the first direction z is referred to as the “second direction x”. The direction orthogonal to the first direction z and the second direction x is referred to as the “third direction y”. In the semiconductor module A10 and the power conversion unit D10, the second direction x corresponds to the vertical direction.

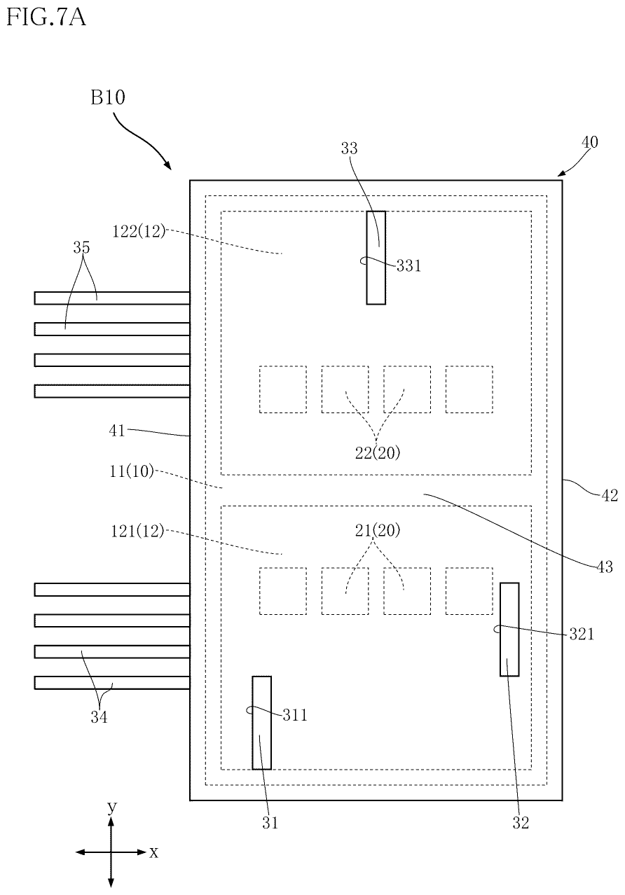

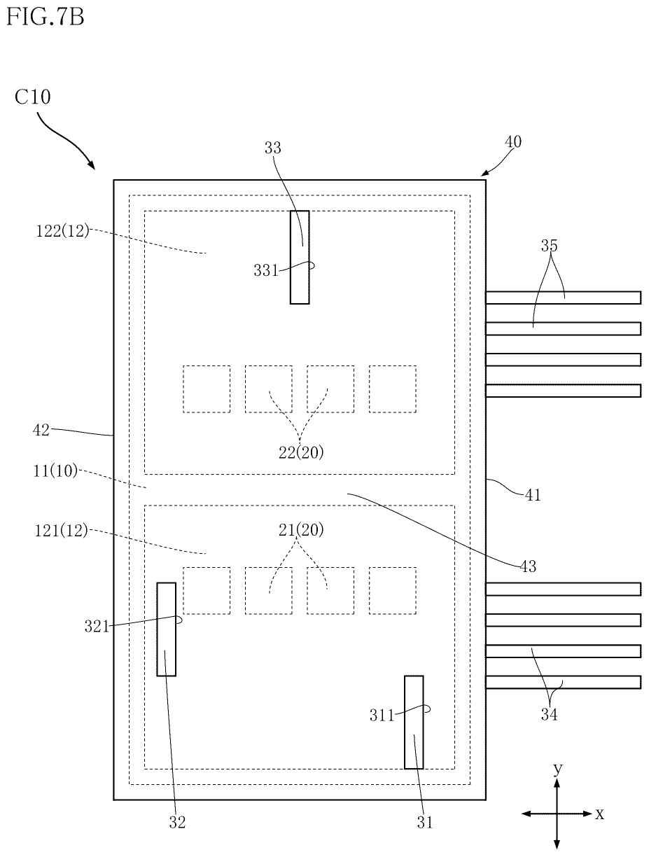

First, the semiconductor device B10 and the additional semiconductor device C10, which are included in the semiconductor module A10, will be described based on FIGS. 7A to 11. The configuration of the additional semiconductor device C10 is the same as that of the semiconductor device B10. Therefore, the description of the additional semiconductor device C10 is omitted. The semiconductor device B10 may include a substrate 10, a plurality of semiconductor elements 20, a first terminal 31, a second terminal 32, a third terminal 33, a plurality of first signal terminals 34, a plurality of second signal terminals 35, and a sealing resin 40.

In each of the semiconductor device B10 and the additional semiconductor device C10, a half bridge circuit including the plurality of semiconductor elements 20 may be formed, as shown in FIG. 11. The semiconductor device B10 may be configured to convert the DC power supplied to the first terminal 31 and the second terminal 32 into AC power by the plurality of semiconductor elements 20. The converted AC power may be inputted from the third terminal 33 to a power supply target, such as a motor.

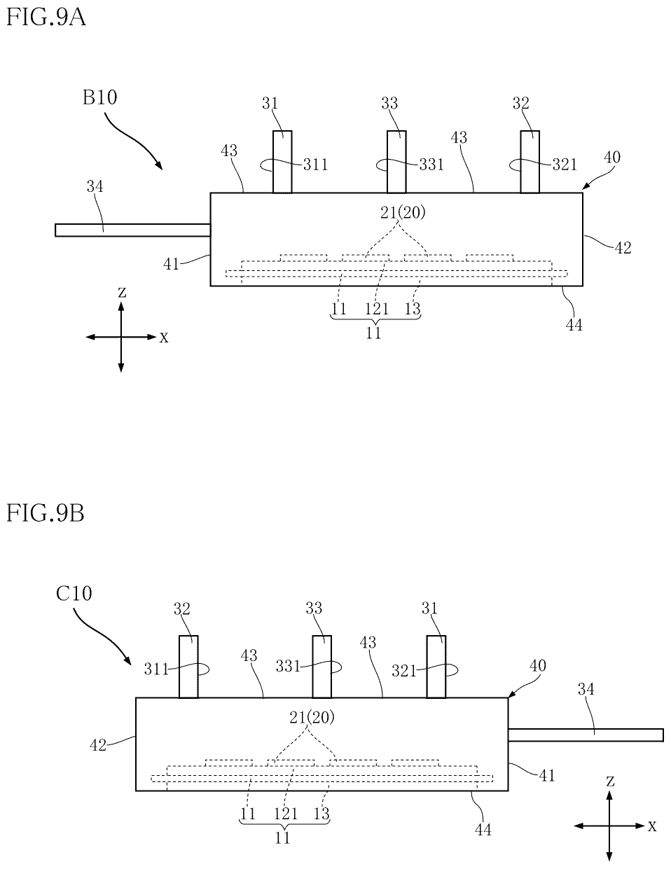

As shown in FIGS. 7A and 7B, the substrate 10 may carry the plurality of semiconductor elements 20. In the semiconductor device B10, for example, the substrate 10 may be obtained from a DBC (Direct Bonded Copper) substrate. As shown in FIGS. 9A and 9B, the substrate 10 may have an insulating layer 11, a first wiring layer 121, a second wiring layer 122, and a heat dissipation layer 13. The substrate 10 may be covered with the sealing resin 40 except a portion of the heat dissipation layer 13.

As shown in FIGS. 9A and 9B, the insulating layer 11 may be located between the first and the second wiring layers 121, 122 and the heat dissipation layer 13 in the first direction z. The insulating layer 11 may be made of a material having relatively high thermal conductivity. The insulating layer 11 may be made of, for example, a ceramic material including aluminum nitride (AlN). The insulating layer 11 may be made of an insulating resin sheet rather than a ceramic material. As shown in FIGS. 9A and 9B, the first wiring layer 121 and the second wiring layer 122 may be located on one side of the insulating layer 11 in the first direction z. The first wiring layer 121 and the second wiring layer 122 may be spaced apart from each other in the third direction y. Each of the first wiring layer 121 and the second wiring layer 122 may be bonded to the insulating layer 11. As viewed in the first direction z, each of the first wiring layer 121 and the second wiring layer 122 may be surrounded by the periphery of the insulating layer 11. The composition of the first wiring layer 121 and the second wiring layer 122 may include copper.

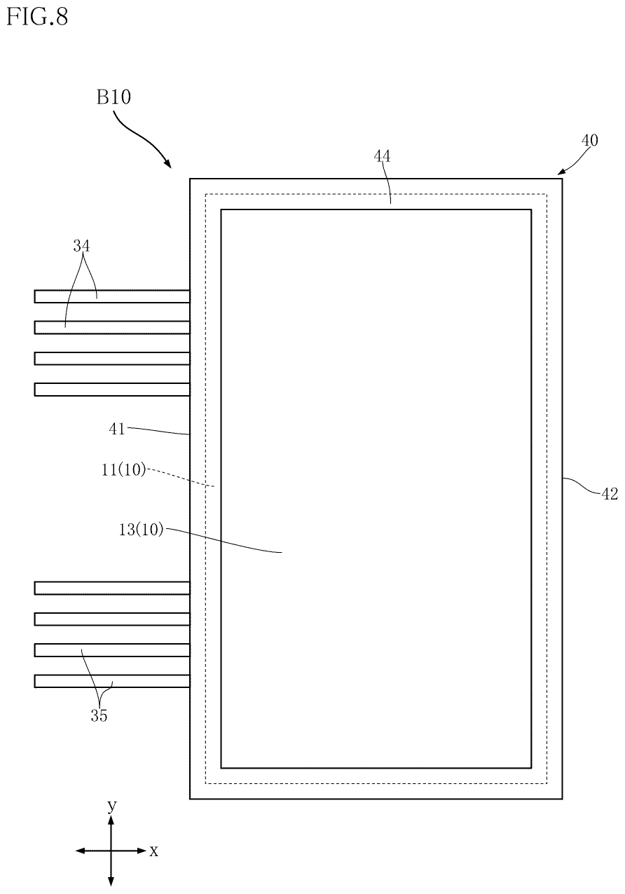

As shown in FIGS. 9A and 9B, the heat dissipation layer 13 may be located opposite to the first wiring layer 121 and the second wiring layer 122 with respect to the insulating layer 11 in the first direction z. As shown in FIG. 8, the heat dissipation layer 13 may be exposed from the sealing resin 40. The composition of the heat dissipation layer 13 may include copper.

Each of the semiconductor elements 20 may be mounted on either the first wiring layer 121 of the substrate 10 or the second wiring layer 122 of the substrate 10, as shown in FIGS. 7A and 7B. The semiconductor elements 20 may be configured as, for example, MOSFETs (Metal-Oxide-Semiconductor Field-Effect Transistors). Alternatively, the semiconductor elements 20 may be configured as various switching elements, such as IGBTs (Insulated Gate Bipolar Transistors). In the semiconductor device B10 described herein, the semiconductor elements 20 are n-channel MOSFETs having a vertical structure. Each of the semiconductor elements 20 may include a compound semiconductor substrate. The composition of the compound semiconductor substrate may include silicon carbide (SiC).

As shown in FIGS. 7A and 7B, the plurality of semiconductor elements 20 may include a plurality of first elements 21 and a plurality of second elements 22. The configuration of each second element 22 may be the same as that of each first element 21. The first elements 21 may be mounted on the first wiring layer 121 of the substrate 10. The first elements 21 may be arranged along the second direction x. The first elements 21 may form the upper arm circuit of the half bridge circuit formed in the semiconductor device B10. The second elements 22 may be mounted on the second wiring layer 122 of the substrate 10. The second elements 22 may be arranged along the second direction x. The second elements 22 may form the lower arm circuit of the half bridge circuit formed in the semiconductor device B10.

Each of the semiconductor elements 20 may have a drain electrode, a source electrode, and a gate electrode. The drain electrode may be located on the side facing the substrate 10 in the first direction z. A current corresponding to the power before conversion by the semiconductor elements 20 may flow in the drain electrode. The source electrode and the gate electrode may be located opposite to the drain electrode in the first direction z. A current corresponding to the power after conversion by the semiconductor element 20 may flow in the source electrode. A gate voltage for driving the semiconductor elements 20 may be applied to the gate electrode.

The drain electrode of each of the first elements 21 may be conductively bonded to the first wiring layer 121 of the substrate 10 via solder or the like. Thus, the drain electrode of each first element 21 may be electrically connected to the first wiring layer 121. The drain electrode of each of the second elements 22 may be conductively bonded to the second wiring layer 122 via solder or the like. Thus, the drain electrode of each second element 22 may be electrically connected to the second wiring layer 122. Also, the source electrode of each of the first elements 21 may be electrically connected to the second wiring layer 122.

The sealing resin 40 may be configured to cover a portion of the substrate 10, and the plurality of semiconductor elements 20, as shown in FIGS. 7A to 10. The sealing resin 40 may have electrical insulation property. The sealing resin 40 may be made of a material including, for example, a black epoxy resin. As shown in FIGS. 9A and 9A, the sealing resin 40 may have a first surface 41, a second surface 42, a third surface 43, and a fourth surface 44.

As shown in FIGS. 9A and 9B, the first surface 41 and the second surface 42 may face away from each other in the second direction x. The third surface 43 and the fourth surface 44 may face away from other in the first direction z. The heat dissipation layer 13 of the substrate 10 may be exposed from the fourth surface 44.

As shown in FIGS. 7A, 7B, 9A, and 9B, each of the first terminal 31, the second terminal 32, and the third terminal 33 may be exposed to the outside from the sealing resin 40. In semiconductor device B10, each of the first terminal 31, the second terminal 32, and the third terminal 33 may be exposed to the outside from the third surface 43 of the sealing resin 40. The first terminal 31 and the second terminal 32 may be spaced apart from each other in the second direction x.

As shown in FIG. 11, the first terminal 31 may be electrically connected to the drain electrode of each of the first elements 21. The first terminal 31 may be electrically connected to the first wiring layer 121 of the substrate 10. The first terminal 31 may correspond to the P terminal (positive pole) of the input terminals of the semiconductor device B10. As shown in FIGS. 7A and 7B, the first terminal 31 may be located closer to the first surface 41 of the sealing resin 40 than are the second terminal 32 and the third terminal 33 in the second direction x. The first terminal 31 may have a first connection surface 311. The first connection surface 311 may protrude outward from the third surface 43 of the sealing resin 40. The first connection surface 311 may face the same side as the first surface 41 of the sealing resin 40 in the second direction x.

As shown in FIG. 11, the second terminal 32 may be electrically connected to the source electrode of each of the second elements 22. The second terminal 32 may correspond to the N terminal (negative pole) of the input terminals of the semiconductor device B10. As shown in FIGS. 7A and 7A, the second terminal 32 may be located closer to the second surface 42 of the sealing resin 40 than are the first terminal 31 and the third terminal 33 in the second direction x. The second terminal 32 may be spaced apart from the first terminal 31 in the third direction y. The second terminal 32 may have a second connection surface 321. The second connection surface 321 may protrude outward from the third surface 43 of the sealing resin 40. The second connection surface 321 may face the same side as the first surface 41 of the sealing resin 40 in the second direction x.

As shown in FIG. 11, the third terminal 33 may be electrically connected to the source electrode of each of the first elements 21 and the drain electrode of each of the second elements 22. The third terminal 33 may be electrically connected to the second wiring layer 122 of the substrate 10. The third terminal 33 may correspond to the output terminal of the semiconductor device B10. As shown in FIGS. 7A and 7B, the third terminal 33 may be located between the first terminal 31 and the second terminal 32 in the second direction x. The third terminal 33 may have a third connection surface 331. The third connection surface 331 may protrude outward from the third surface 43 of the sealing resin 40. The third connection surface 331 may face the same side as the first surface 41 of the sealing resin 40 in the second direction x.

The plurality of first signal terminals 34 may protrude outward from the first surface 41 of the sealing resin 40 as shown in FIGS. 9A and 9B. The first signal terminals 34 may include a first gate terminal 341 and a first detection terminal 342. As shown in FIG. 11, the first gate terminal 341 may be electrically connected to the gate electrode of each of the first elements 21. A gate voltage for driving the first elements 21 may be applied to the first gate terminal 341. As shown in FIG. 11, the first detection terminal 342 may be electrically connected to the source electrode of each of the first elements 21. A voltage equivalent to the voltage applied to the source electrode of each first element 21 may be applied to the first detection terminal 342.

The plurality of second signal terminals 35 may protrude outward from the first surface 41 of the sealing resin 40 as shown in FIGS. 9A and 9B. The second signal terminals 35 may be located opposite to the first terminal 31 with respect to the first signal terminals 34 in the third direction y. The second signal terminals 35 may include a second gate terminal 351 and a second detection terminal 352. As shown in FIG. 11, the second gate terminal 351 may be electrically connected to the gate electrode of each of the second elements 22. A gate voltage for driving the second elements 22 may be applied to the second gate terminal 351. As shown in FIG. 11, the second detection terminal 352 may be electrically connected to the source electrode of each of the second elements 22. A voltage equivalent to the voltage applied to the source electrode of each second element 22 may be applied to the second detection terminal 352.

Next, the heat dissipation member 50 included in the semiconductor module A10, and the cooler 60 and the capacitor 70 included in the power conversion unit D10 will be described based on FIGS. 1 to 6.

The heat dissipation member 50 and the cooler 60 are used to cool the semiconductor device B10 and the additional semiconductor device C10. Each of the heat dissipation member 50 and the cooler 60 may be made of a material containing, for example, aluminum.

The heat dissipation member 50 may support the semiconductor device B10 and the additional semiconductor device C10 as shown in FIGS. 1 to 5. The heat dissipation member 50 may have a base portion 51 and a support portion 52.

As shown in FIG. 1, the base portion 51 is a flat plate extending in the third direction y. The base portion 51 may support the support portion 52.

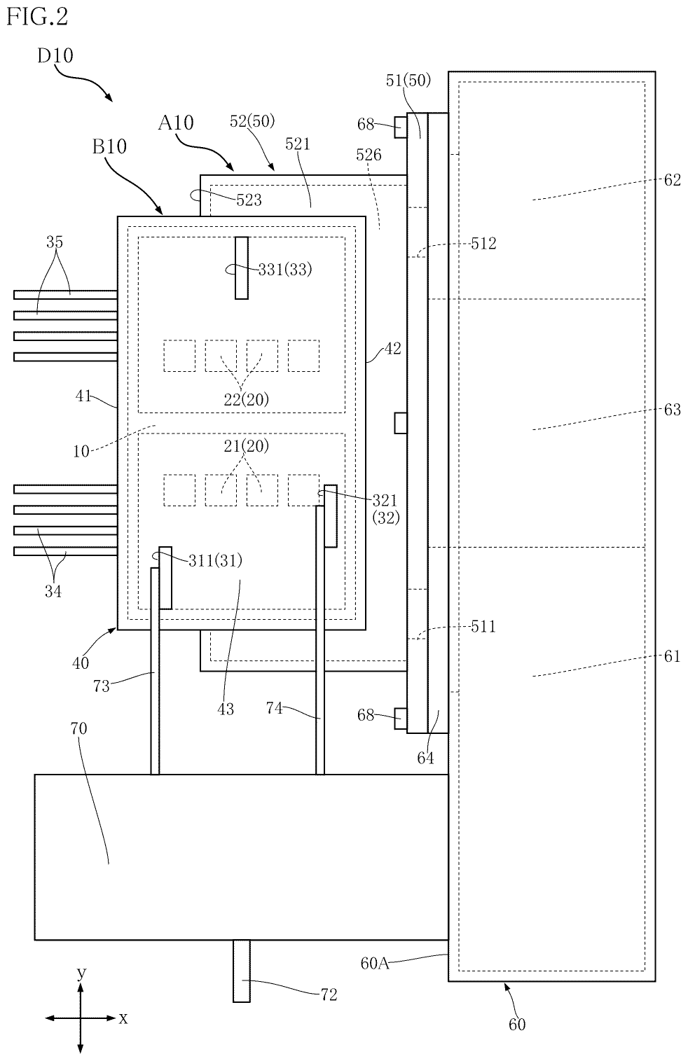

As shown in FIGS. 2 to 5, the support portion 52 may stand on the base portion 51 in the second direction x. The support portion 52 may have a first support surface 521, a second support surface 522, and a top surface 523. The first support surface 521 and the second support surface 522 may face away from each other in the first direction z. The heat dissipation layer 13 of the substrate 10 of the semiconductor device B10 may be supported on the first support surface 521. The semiconductor device B10 may extend farther than the first support surface 521. The heat dissipation layer 13 of the substrate 10 of the additional semiconductor device C10 may be supported on the second support surface 522. The additional semiconductor device C10 may extend farther than the second support surface 522.

As shown in FIGS. 2 to 5, the top surface 523 may face the same side as the first surface 41 of the sealing resin 40 of each of the semiconductor device B10 and the additional semiconductor device C10 in the second direction x. In the second direction x, the top surface 523 may be located between the first surface 41 and the second surface 42 of the sealing resin 40 of the semiconductor device B10. Also, in the second direction x, the top surface 523 may be located between the first surface 41 and the second surface 42 of the sealing resin 40 of the additional semiconductor device C10.

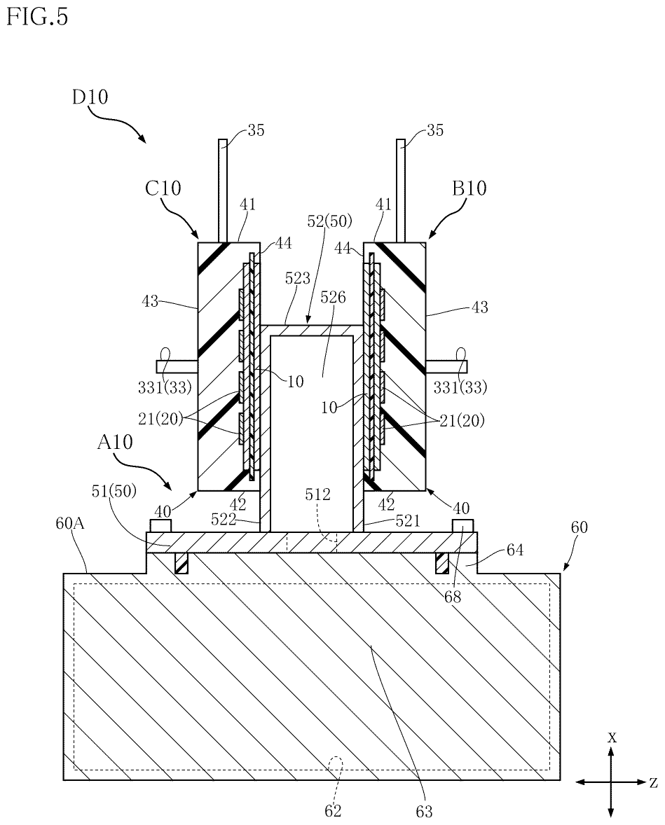

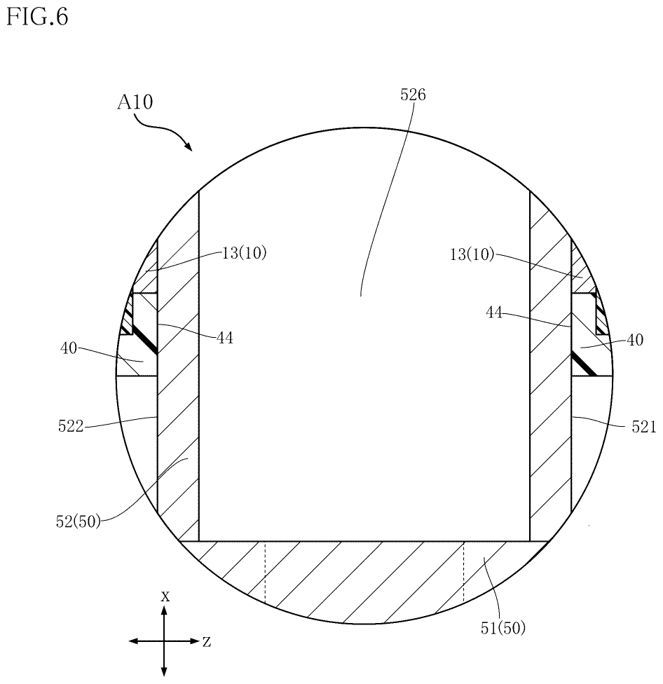

As shown in FIGS. 5 and 6, the sealing resin 40 of the semiconductor device B10 may be in contact with the first support surface 521. The sealing resin 40 of the additional semiconductor device C10 may be in contact with the second support surface 522. In the semiconductor module A10, during the formation of the sealing resin 40 of each of the semiconductor device B10 and the additional semiconductor device C10, a portion of each of the first support surface 521 and the second support surface 522 may be sealed by the sealing resin 40.

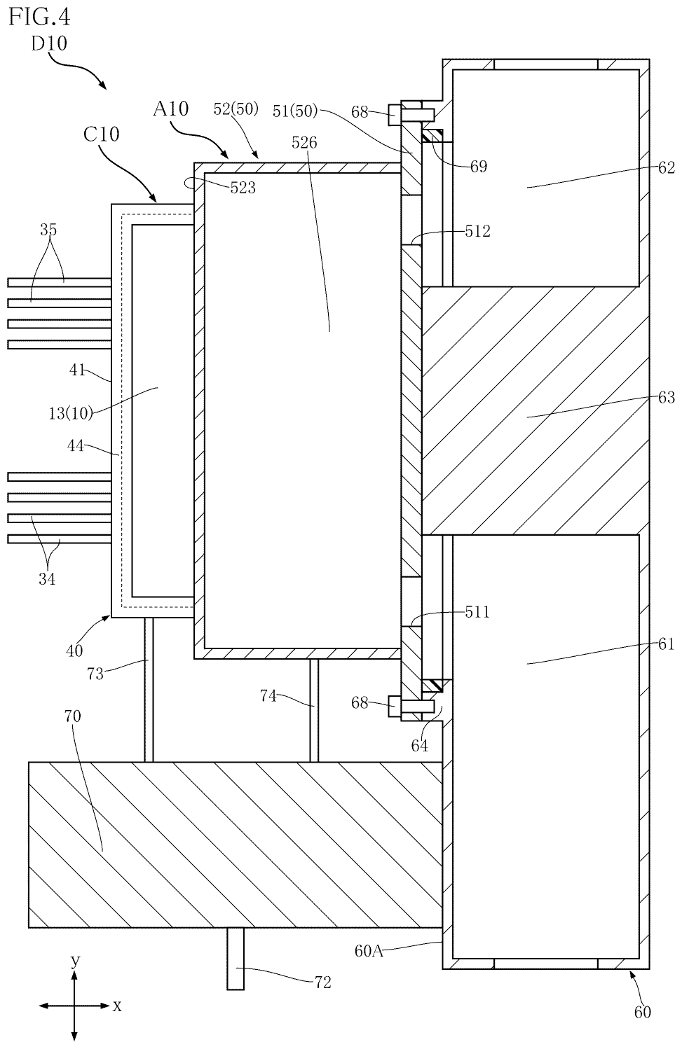

As shown in FIGS. 4 and 5, the heat dissipation member 50 may include a hollow portion 526 inside the support portion 52. As viewed in the first direction z, the substrate 10 of the semiconductor device B10 and the substrate 10 of the additional semiconductor device C10 may overlap with the hollow portion 526.

As shown in FIGS. 1 and 5, the heat dissipation member 50 may include an inlet 511 and an outlet 512. Each of the inlet 511 and outlet 512 may be open at the base portion 51 and connected to the hollow portion 526. The inlet 511 and outlet port 512 may be located opposite to the top surface 523 of the support portion 52 with respect to the second surface 42 of the sealing resin 40 of each of the semiconductor device B10 and the additional semiconductor device C10 in the second direction x. In the heat dissipation member 50, a coolant may flow from the inlet 511 into the hollow portion 526. The coolant flowing into the hollow portion 526 may be discharged from the outlet 512.

The cooler 60 may support the heat dissipation member 50, as shown in FIGS. 1 to 5. The cooler 60 may have a mount surface 60A, a first flow path 61, a second flow path 62, a separating portion 63, and a seat portion 64.

As shown in FIGS. 2 to 5, the mount surface 60A may face the same side as the top surface 523 of the heat dissipation member 50 in the second direction x. Each of the first flow path 61 and the second flow path 62 may be located inside the cooler 60. As viewed in the first direction z, the first flow path 61 and the second flow path 62 may be surrounded by the mount surface 60A. The first flow path 61 may be connected to the inlet 511 of the heat dissipation member 50. The second flow path 62 may be connected to the outlet 512 of the heat dissipation member 50. In the semiconductor module A10, the coolant may flow from first flow path 61 into the hollow portion 526 of the heat dissipation member 50 through the inlet 511. The coolant may cool each of the semiconductor device B10 and the additional semiconductor device C10 via the heat dissipation member 50. The coolant flowing into the hollow portion 526 may then flow down to the second flow path 62 through the outlet 512. The coolant flowing down into the second flow path 62 may be discharged to the outside of the semiconductor module A10.

As shown in FIGS. 2, 4, and 5, the separating portion 63 may be located inside the cooler 60. The separating portion 63 may separate the first flow path 61 and the second flow path 62. The seat portion 64 may protrude from the mount surface 60A in the second direction x. As viewed in the first direction z, the seat portion 64 may surround the first flow path 61, the second flow path 62, and the separating portion 63. In the process of having the cooler 60 support the heat dissipation member 50, a sealing material 69 surrounding the inner periphery of the seat portion 64 may be attached to the cooler 60. The sealing material 69 can prevent leakage of the coolant flowing into the semiconductor module A10. After the sealing material 69 is attached to the cooler 60, the base portion 51 of the heat dissipation member 50 may be disposed on the separating portion 63 and the seat portion 64. The base portion 51 may then be fixed to the seat portion 64 using fastening members 68, such as bolts. Thus, the heat dissipation member 50 can be supported on the cooler 60, and it is possible to flow the coolant through the semiconductor module A10 by passing from the first flow path 61 to the second flow path 62 via the hollow portion 526 of the heat dissipation member 50.

The capacitor 70 may be supported on the mount surface 60A of the cooler 60 as shown in FIGS. 2 and 4. The capacitor 70 may be connected to the first terminal 31 and the second terminal 32 of each of the semiconductor device B10 and the additional semiconductor device C10. The capacitor 70 may supply DC power to each of the semiconductor device B10 and the additional semiconductor device C10. Furthermore, the capacitor 70 can store a charge corresponding to the DC power.

As shown in FIGS. 1 and 2, the capacitor 70 may have a first input terminal 71, a second input terminal 72, two first conductive members 73, and two second conductive members 74. The first input terminal 71 and each of the two first conductive members 73 may be electrically connected to one of the electrodes of the capacitor 70. The second input terminal 72 and each of the two second conductive members 74 may be electrically connected to the other electrode of the capacitor 70. The first input terminal 71 and the second input terminal 72 may be connected to a DC power supply located outside the semiconductor module A10. The two first conductive members 73 may be individually connected to the first connection surfaces 311 of the first terminals 31 of the semiconductor device B10 and the additional semiconductor device C10. The two second conductive members 74 may be individually connected to the second connection surfaces 321 of the second terminals 32 of the semiconductor device B10 and the additional semiconductor device C10.

The power conversion unit D10 described herein includes a single semiconductor module A10. In the case where the power conversion unit D10 includes three semiconductor modules A10, like an inverter that drives a motor, the respective numbers of first conductive members 73 and second conductive members 74 may increase in accordance with the number of semiconductor modules A10.

Next, the effects of the semiconductor module A10 will be described.

The semiconductor module A10 may include the semiconductor device B10 and the heat dissipation member 50. The semiconductor device B10 may include the substrate 10, the semiconductor element 20 mounted on the substrate 10, and the sealing resin 40 covering the semiconductor element 20. The substrate 10 may be exposed from the sealing resin 40. The heat dissipation member 50 may have the first support surface 521 and the second support surface 522 facing away from each other in the first direction z. The substrate 10 may be supported on the first support surface 521. By adopting this configuration, it is possible to stand the heat dissipation member 50 in a direction orthogonal to the first direction z. Thus, the present configuration can make the semiconductor module A10 more compact while increasing the cooling efficiency for the semiconductor device B10.

The semiconductor module A10 may further include the additional semiconductor device C10 including the substrate 10, the semiconductor element 20, and the sealing resin 40. The substrate 10 of the additional semiconductor device C10 may be supported on the second support surface 522 of the heat dissipation member 50. By adopting this configuration, it is possible to cool the semiconductor device B10 and the additional semiconductor device C10 with a single heat dissipation member 50 while making the semiconductor module A10 more compact.

The semiconductor device B10 may extend farther than the first support surface 521 of the heat dissipation member 50. In addition, the additional semiconductor device C10 may extend farther than the second support surface 522 of the heat dissipation member 50. By adopting this configuration, it is possible to reduce the size of the heat dissipation member 50 within a range that does not impair the cooling efficiency for the semiconductor device B10 and the additional semiconductor device C10.

In the above configuration, the heat dissipation member 50 may have the top surface 523 facing the same side as the first surface 41 of the sealing resin 40 of each of the semiconductor device B10 and the additional semiconductor device C10 in the second direction x. In the second direction x, the top surface 523 may be located between the first surface 41 and the second surface 42 of the sealing resin 40 of the semiconductor device B10. Also, the top surface 523 may be located between the first surface 41 and the second surface 42 of the sealing resin 40 of the additional semiconductor device C10. By adopting this configuration, when the heat dissipation member 50 is configured to stand in the second direction x, the semiconductor module A10 can be made further compact.

The first terminal 31 and the second terminal 32 may be exposed to the outside from the third surface 43 of the sealing resin 40. In this case, the first connection surface 311 of the first terminal 31 and the second connection surface 321 of the second terminal 32 may face the same side as the first surface 41 of the sealing resin 40 in the second direction x. By adopting this configuration, in the power conversion unit D10, the first conductive member 73 of the capacitor 70 can be supported in a stable state on the first connection surface 311. Also, the second conductive member 74 of the capacitor 70 can be supported in a stable state on the second connection surface 321.

The heat dissipation member 50 may include a hollow portion 526 inside the heat dissipation member 50. As viewed in the first direction z, the substrate 10 of the semiconductor device B10 and the substrate 10 of the additional semiconductor device C10 may overlap with the hollow portion 526. By adopting this configuration, when the coolant flows into the hollow portion 526, heat can be quickly conducted from each of the semiconductor device B10 and the additional semiconductor device C10 to the coolant.

The heat dissipation member 50 may include the inlet 511 and the outlet 512 each of which is connected to the hollow portion 526. The inlet 511 and outlet 512 may be located opposite to the top surface 523 of the heat dissipation member 50 with respect to the second surface 42 of the sealing resin 40 in the second direction x. With such a configuration, because the inlet 511 and outlet 512 are spaced apart from the semiconductor device B10 and the additional semiconductor device C10 in the second direction x, the supply of the coolant from the cooler 60 to the heat dissipation member 50 can be performed smoothly in the power conversion unit D10.

### Second Embodiment

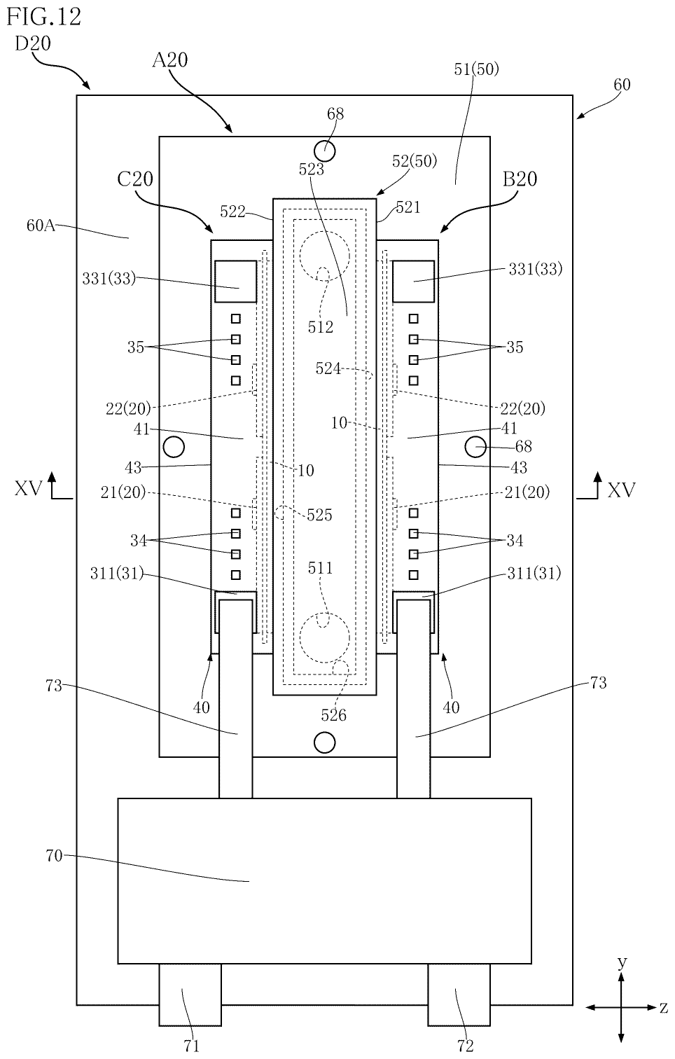

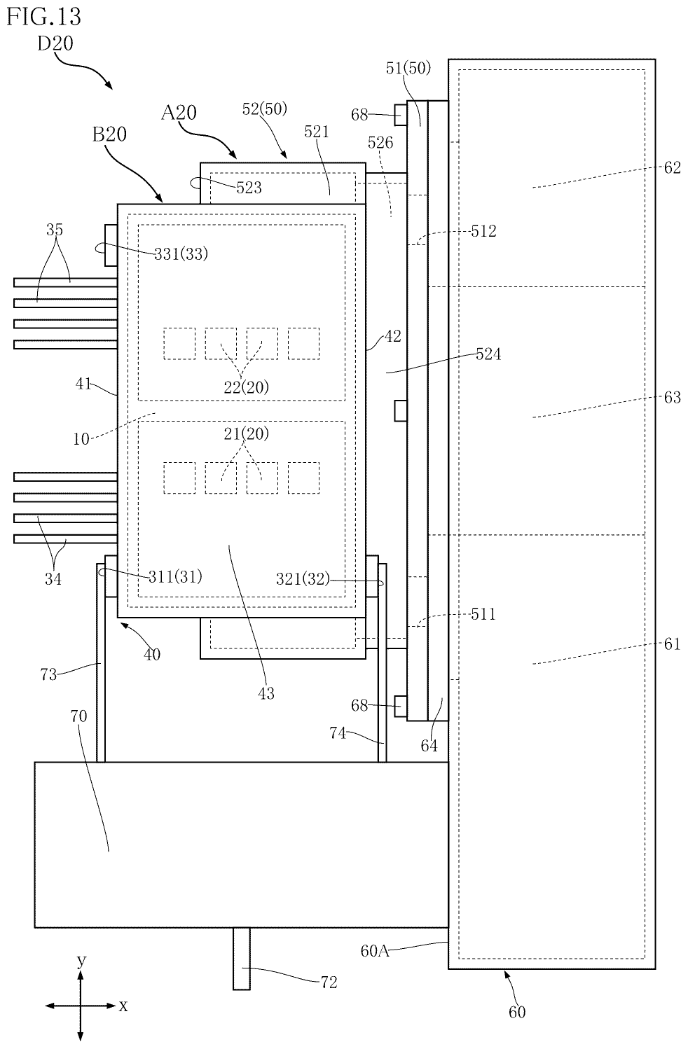

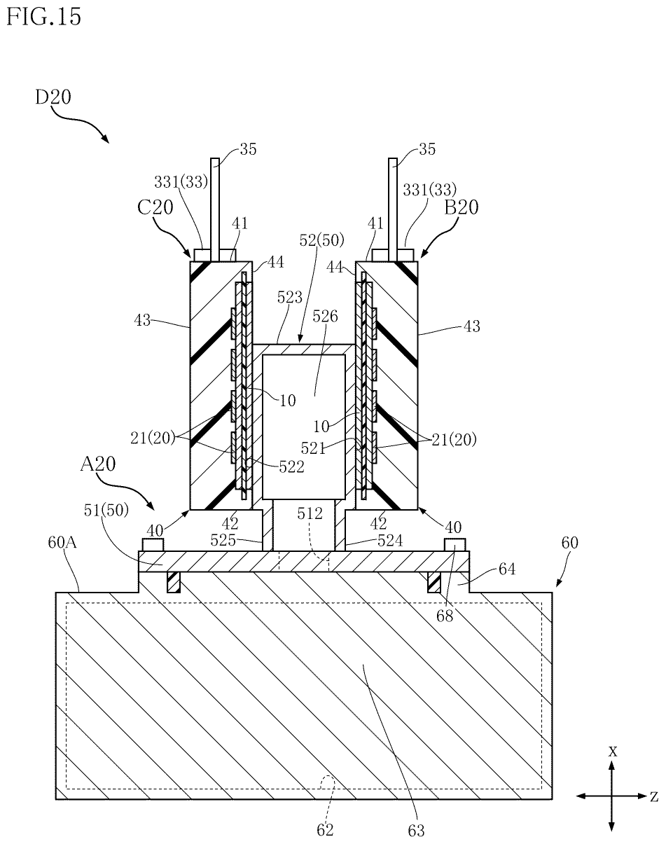

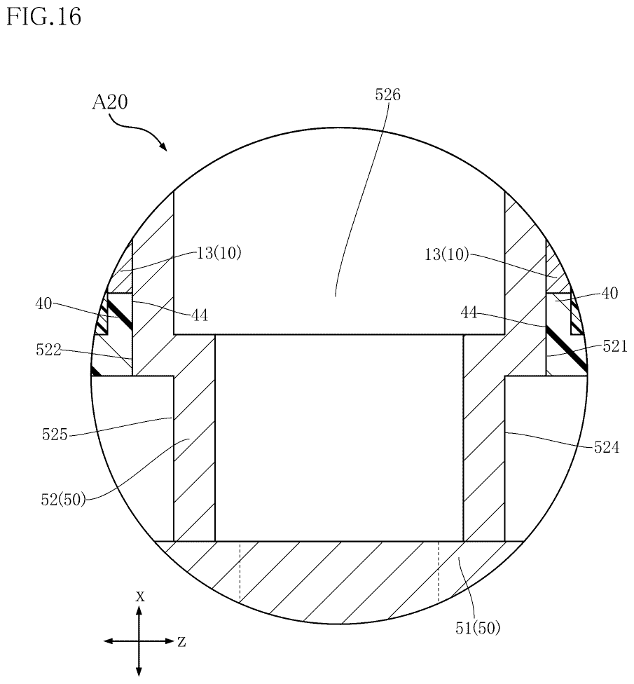

A semiconductor module A20 and a power conversion unit D20 according to a second embodiment of the present disclosure will be described based on FIGS. 12 to 16. In these figures, the elements that are identical or similar to those of the semiconductor module A10 and the power conversion unit D10 described above are denoted by the same reference signs, and the descriptions thereof are omitted.

The semiconductor module A20 may include a semiconductor device B20, an additional semiconductor device C20, and a heat dissipation member 50. The power conversion unit D20 may include the semiconductor module A20, a cooler 60, and a capacitor 70. In the semiconductor module A20, the configurations of the first terminals 31, the second terminals 32, and the third terminals 33 of the semiconductor device B20 and the additional semiconductor device C20 may differ from those of the semiconductor device B10 and the additional semiconductor device C10. Also, in the semiconductor module A20, the configuration of the heat dissipation member 50 may differ from that of the semiconductor module A10.

As shown in FIGS. 12 to 14, the first terminal 31 may be exposed to the outside from the first surface 41 of the sealing resin 40. The first connection surface 311 of the first terminal 31 may protrude outward from the first surface 41. The second terminal 32 may be exposed to the outside from the second surface 42 of the sealing resin 40. The second connection surface 321 of the second terminal 32 may protrude outward from the second surface 42. The third terminal 33 may be exposed to the outside from the first surface 41. The third connection surface 331 of the third terminal 33 may protrude outward from the first surface 41.

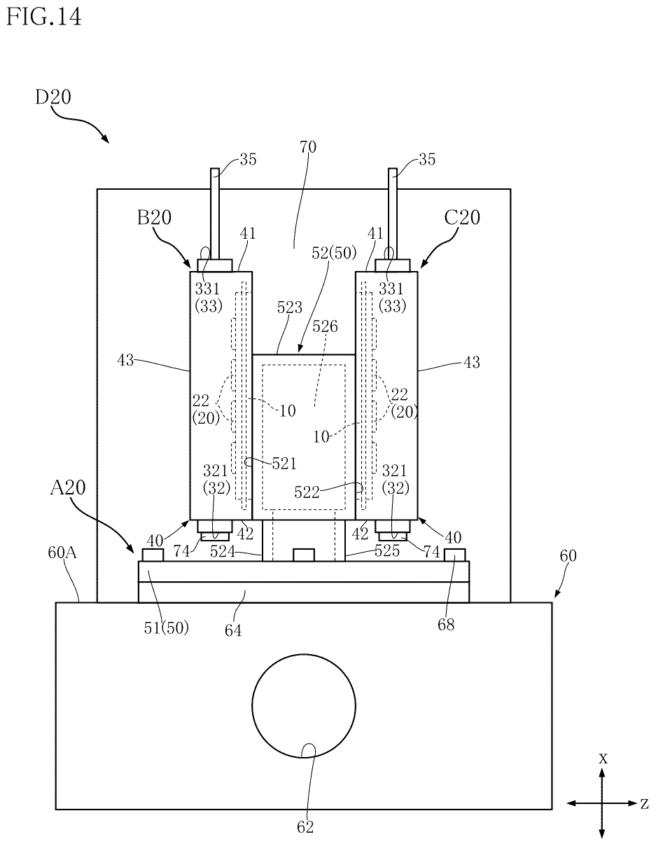

As shown in FIGS. 14 to 16, the support portion 52 of the heat dissipation member 50 may have a first base surface 524 and a second base surface 525 that face away from each other in the first direction z. The first base surface 524 may face the same side as the first support surface 521 in the first direction z. The first base surface 524 may be located opposite to the top surface 523 with respect to the first support surface 521 in the second direction x. The first base surface 524 may be farther away from the semiconductor device B20 than is the first support surface 521 in the first direction z. As viewed in the first direction z, the first base surface 524 may overlap with the second connection surface 321 of the second terminal 32 of the semiconductor device B20. The second base surface 525 may face the same side as the second support surface 522 in the first direction z. The second base surface 525 may be located opposite to the top surface 523 with respect to the second support surface 522 in the second direction x. The second base surface 525 may be farther away from the additional semiconductor device C20 than is the second support surface 522 in the first direction z. As viewed in the first direction z, the second base surface 525 may overlap with the second connection surface 321 of the second terminal 32 of the additional semiconductor device C20.

Next, the effects of the semiconductor module A20 and the power conversion unit D20 will be described.

The semiconductor module A20 may include the semiconductor device B20 and the heat dissipation member 50. The semiconductor device B20 may include the substrate 10, the semiconductor element 20 mounted on the substrate 10, and the sealing resin 40 covering the semiconductor element 20. The substrate 10 may be exposed from the sealing resin 40. The heat dissipation member 50 may have the first support surface 521 and the second support surface 522 facing away from each other in the first direction z. The substrate 10 may be supported on the first support surface 521. The present configuration can make the semiconductor module A20 more compact while increasing the cooling efficiency for the semiconductor device B20. Furthermore, the semiconductor device A20 has a configuration in common with the semiconductor device A10, thereby achieving the same effect as the semiconductor device A10.

In the semiconductor module A20, the second terminal 32 of the semiconductor device B20 may be exposed to the outside from the second surface 42 of the sealing resin 40. In this case, the heat dissipation member 50 may have the first base surface 524 facing the same side as the first support surface 521 in the first direction z. The first base surface 524 may be farther away from the semiconductor device B20 than is the first support surface 521 in the first direction z. As viewed in the first direction z, the first base surface 524 may overlap with the second connection surface 321 of the second terminal 32 of the semiconductor device B20. By adopting this configuration, when connecting the second conductive member 74 of the capacitor 70 to the second terminal 32 of the semiconductor device B20 in the power conversion unit D20, it is possible to more reliably prevent the second conductive member 74 from coming into contact with the heat dissipation member 50.

### Third Embodiment

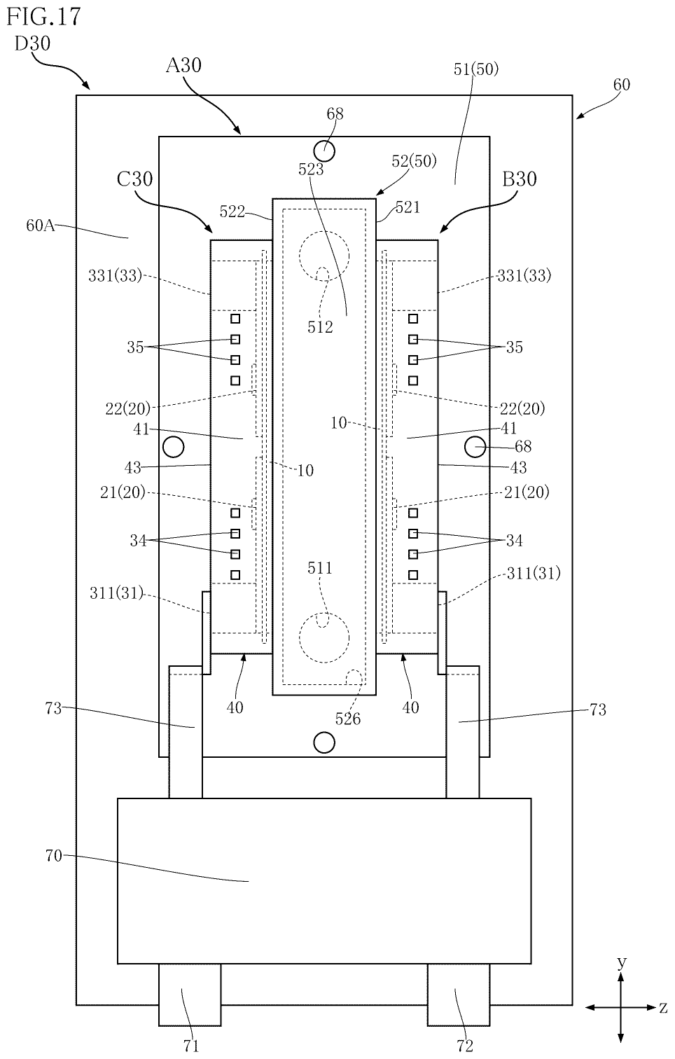

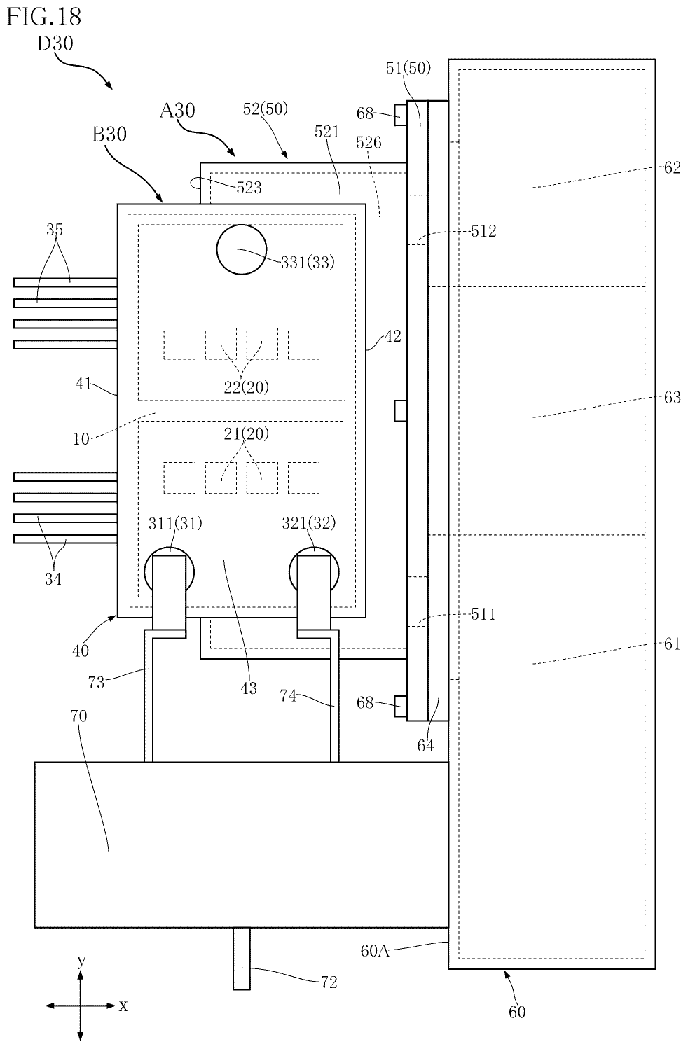

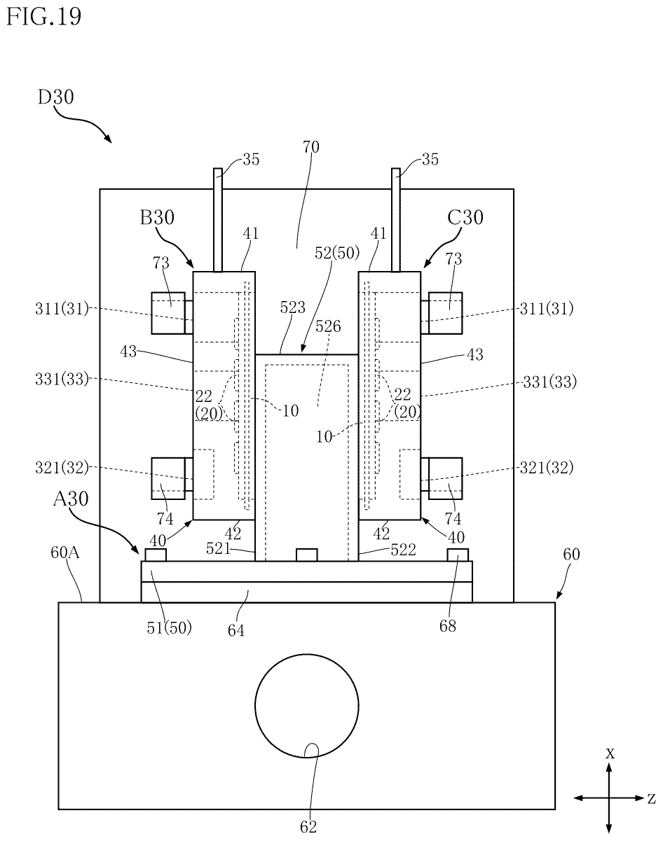

A semiconductor module A30 and a power conversion unit D30 according to a third embodiment of the present disclosure will be described based on FIGS. 17 to 19. In these figures, the elements that are identical or similar to those of the semiconductor module A10 described above are denoted by the same reference signs, and the descriptions thereof are omitted.

The semiconductor module A30 may include a semiconductor device B30, an additional semiconductor device C30, and a heat dissipation member 50. The power conversion unit D30 may include the semiconductor module A30, a cooler 60, and a capacitor 70. In the semiconductor module A30, the configurations of the first terminals 31, the second terminals 32, and the third terminals 33 of the semiconductor device B30 and the additional semiconductor device C30 may differ from those of the semiconductor device B10 and the additional semiconductor device C10

As shown in FIGS. 17 to 19, each of the first connection surface 311 of the first terminal 31, the second connection surface 321 of the second terminal 32, and the third connection surface 331 of the third terminal 33 may be flush with the third surface 43 of the sealing resin 40. Thus, the first connection surface 311, the second connection surface 321, and the third connection surface 331 may not protrude outward from the third surface 43. Alternatively, each of the first connection surface 311, the second connection surface 321, and the third connection surface 331 may be located between the third surface 43 and the fourth surface 44 in the first direction z.

Next, the effects of the semiconductor module A30 will be described.

The semiconductor module A30 may include the semiconductor device B30 and the heat dissipation member 50. The semiconductor device B30 may include the substrate 10, the semiconductor element 20 mounted on the substrate 10, and the sealing resin 40 covering the semiconductor element 20. The substrate 10 may be exposed from the sealing resin 40. The heat dissipation member 50 may have the first support surface 521 and the second support surface 522 facing away from each other in the first direction z. The substrate 10 may be supported on the first support surface 521. The present configuration can make the semiconductor module A30 more compact while increasing the cooling efficiency for the semiconductor device B30. Furthermore, the semiconductor device A30 has a configuration in common with the semiconductor device A10, thereby achieving the same effect as the semiconductor device A10.

### Fourth Embodiment

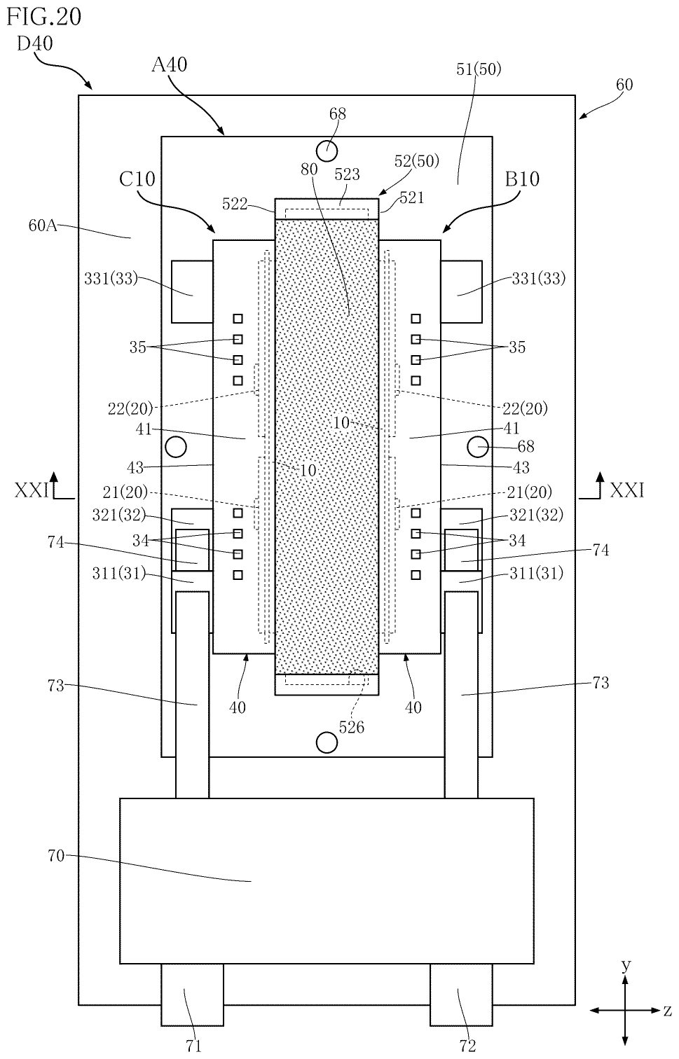

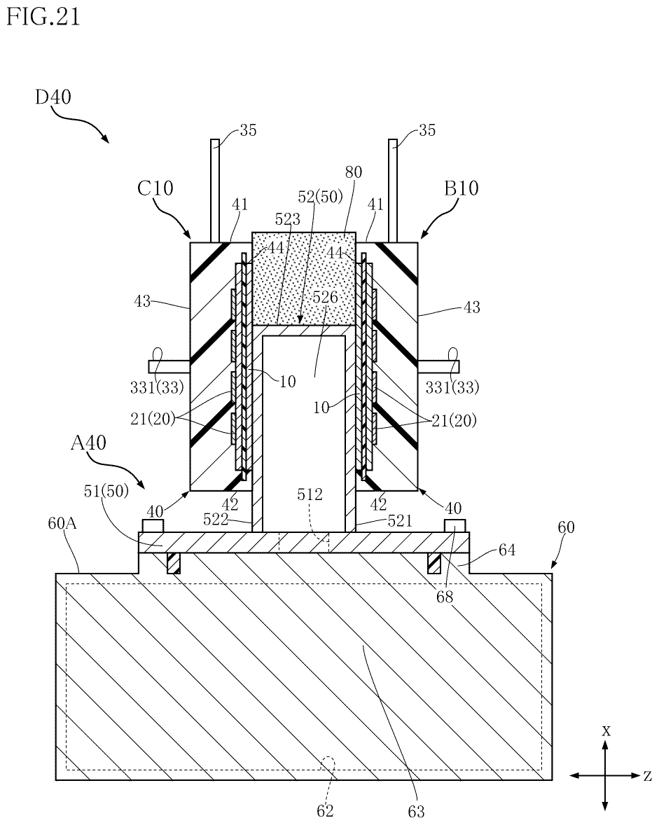

A semiconductor module A40 and a power conversion unit D40 according to a fourth embodiment of the present disclosure will be described based on FIGS. 20 and 21. In these figures, the elements that are identical or similar to those of the semiconductor module A10 described above are denoted by the same reference signs, and the descriptions thereof are omitted.

The semiconductor module A40 may further include a spacer 80 in addition to the semiconductor device B10, the additional semiconductor device C10, and the heat dissipation member 50. The power conversion unit D40 may include the semiconductor module A40, a cooler 60, and capacitor 70.

The spacer 80 may be sandwiched between the semiconductor device B10 and the additional semiconductor device C10 as shown in FIGS. 20 and 21. The spacer 80 may be an insulator. The spacer 80 may be made of, for example, hard rubber. As viewed in the second direction x, the spacer 80 may overlap with the top surface 523 of the heat dissipation member 50. The spacer 80 may be bonded to the top surface 523. The spacer 80 may protrude in the second direction x from the first surface 41 of the sealing resin 40 of each of the semiconductor device B10 and the additional semiconductor device C10.

Next, the effects of the semiconductor module A40 will be described.

The semiconductor module A40 may include the semiconductor device B10 and the heat dissipation member 50. The semiconductor device B10 may include the substrate 10, the semiconductor element 20 mounted on the substrate 10, and the sealing resin 40 covering the semiconductor element 20. The substrate 10 may be exposed from the sealing resin 40. The heat dissipation member 50 may have the first support surface 521 and the second support surface 522 facing away from each other in the first direction z. The substrate 10 may be supported on the first support surface 521. The present configuration can make the semiconductor module A40 more compact while increasing the cooling efficiency for the semiconductor device B10. Furthermore, the semiconductor device A40 has a configuration in common with the semiconductor device A10, thereby achieving the same effect as the semiconductor device A10.

The semiconductor module A40 may further include the spacer 80 sandwiched between the semiconductor device B10 and the additional semiconductor device C10. As viewed in the second direction x, the spacer 80 may overlap with the top surface 523 of the heat dissipation member 50. By adopting this configuration, the portion of the semiconductor device B10 that extends farther than the first support surface 521 of the heat dissipation member 50 and the portion of the additional semiconductor device C10 that extends farther than the second support surface 522 of the heat dissipation member 50 can be supported by the spacer 80. This can stabilize the posture of the semiconductor device B10 and the additional semiconductor device C10 with respect to the heat dissipation member 50.

The present disclosure is not limited to the embodiments described above. Various modifications in design may be made freely in the specific structure of each part of the present disclosure.

The present disclosure may include the embodiments described in the following clauses.

### Clause 1

A semiconductor module comprising:
a semiconductor device including a substrate, a semiconductor element mounted on the substrate, and a sealing resin covering the semiconductor element; and
a heat dissipation member, wherein
the substrate is exposed from the sealing resin,
the heat dissipation member includes a first support surface and a second support surface facing away from each other in a first direction, and
the substrate is supported on the first support surface.

### Clause 2

The semiconductor module according to clause 1, wherein the semiconductor device extends farther than the first support surface.

### Clause 3

The semiconductor module according to clause 2, wherein the sealing resin includes a first surface and a second surface facing away from each other in a second direction orthogonal to the first direction,
the heat dissipation member includes a top surface facing a same side as the first surface in the second direction, and
the top surface is located between the first surface and the second surface in the second direction.

### Clause 4

The semiconductor module according to clause 3, wherein the semiconductor element includes a first element and a second element,
the semiconductor device includes a first terminal electrically connected to the first element, a second terminal electrically connected to the second element, and a third terminal electrically connected to the first element and the second element, and
each of the first terminal, the second terminal, and the third terminal is exposed outside from the sealing resin.

### Clause 5

The semiconductor module according to clause 4, wherein the semiconductor device includes a plurality of signal terminals,
at least one of the plurality of signal terminals is electrically connected to the semiconductor element, and
each of the plurality of signal terminals protrudes outward from the first surface.

### Clause 6

The semiconductor module according to clause 5, wherein the sealing resin includes a third surface facing a same side as the first support surface in the first direction, and
each of the first terminal and the second terminal is exposed outside from the third surface.

### Clause 7

The semiconductor module according to clause 6, wherein the first terminal and the second terminal are spaced apart from each other in the second direction.

### Clause 8

The semiconductor module according to clause 7, wherein the first terminal includes a first connection surface protruding outward from the third surface,
the second terminal includes a second connection surface protruding outward from the third surface, and
each of the first connection surface and the second connection surface faces the same side as the first surface in the second direction.

### Clause 9

The semiconductor module according to clause 5, wherein the first terminal is exposed outside from the first surface, and
the second terminal is exposed outside from the second surface.

### Clause 10

The semiconductor module according to clause 9, wherein the heat dissipation member includes a first base surface facing the same side as the first support surface in the first direction,
the first base surface is located opposite to the top surface with respect to the first support surface in the second direction, and
the first base surface is farther away from the semiconductor device than is the first support surface in the first direction.

### Clause 11

The semiconductor module according to any one of clauses 4 to 10, further comprising an additional semiconductor device including the substrate, the semiconductor element, and the sealing resin, wherein
the substrate of the additional semiconductor device is exposed from the sealing resin of the additional semiconductor device,
the substrate of the additional semiconductor device is supported on the second support surface, and
the additional semiconductor device extends farther than the second support surface to a side where the top surface is located in the first direction.

### Clause 12

The semiconductor module according to clause 11, wherein the heat dissipation member includes a hollow portion located inside the heat dissipation member, and
as viewed in the first direction, each of the substrate of the semiconductor device and the substrate of the additional semiconductor device overlaps with the hollow portion.

### Clause 13

The semiconductor module according to clause 12, wherein the heat dissipation member includes an inlet and an outlet each of which is connected to the hollow portion, and
the inlet and the outlet are located opposite to the top surface with respect to the second surface in the second direction.

### Clause 14

The semiconductor module according to clause 13, wherein the sealing resin of the semiconductor device is in contact with the first support surface, and
the sealing resin of the additional semiconductor device is in contact with the second support surface.

### Clause 15

The semiconductor module according to clause 14, further comprising a spacer sandwiched between the semiconductor device and the additional semiconductor device, wherein the spacer overlaps with the top surface as viewed in the second direction.

### Clause 16

A power conversion unit comprising:
the semiconductor module as set forth in clause 13; and
a cooler, wherein
the heat dissipation member is supported on the cooler,
the cooler includes a first flow path and a second flow path each of which is located inside the cooler,
the first flow path is connected to the inlet, and
the second flow path is connected to the outlet.

### Clause 17

The power conversion unit according to clause 16, further comprising a capacitor connected to the first terminal and the second terminal,
wherein the capacitor is supported on the cooler.

### REFERENCE NUMERALS

A10, A20, A30, A40: Semiconductor module
B10, B20, B30: Semiconductor device
C10, C20, C30: Additional semiconductor device
D10, D20, D30, D40: Power conversion unit 10: Substrate
11: Insulating layer 121: First wiring layer
122: Second wiring layer 13: Heat dissipation layer
20: Semiconductor element 21: First element
22: Second element 31: First terminal
311: First connection surface 32: Second terminal
321: Second connection surface 33: Third terminal
331: Third connection surface 34: First signal terminal
341: First gate terminal 342: First detection terminal
35: Second signal terminal 351: Second gate terminal
352: Second detection terminal 40: Sealing resin
41: First surface 42: Second surface
43: Third surface 44: Fourth surface
50: Heat dissipation member 51: Base portion
511: Inlet 512: Outlet
52: Support portion 521: First support surface
522: Second support surface 523: Top surface
524: First base surface 525: Second base surface
526: Hollow portion 60: Cooler
60A: Mount surface 61: First flow path
62: Second flow path 63: Separating portion
64: Seat portion 68: Fastening member
69: Sealing material 70: Capacitor
71: First input terminal 72: Second input terminal
73: First conductive member 74: Second conductive member
80: Spacer z: First direction
x: second direction y: third direction

1. A semiconductor module comprising:
a semiconductor device including a substrate, a semiconductor element mounted on the substrate, and a sealing resin covering the semiconductor element; and
a heat dissipation member, wherein
the substrate is exposed from the sealing resin,
the heat dissipation member includes a first support surface and a second support surface facing away from each other in a first direction, and
the substrate is supported on the first support surface.

2. The semiconductor module according to claim 1, wherein the semiconductor device extends farther than the first support surface.

3. The semiconductor module according to claim 2, wherein the sealing resin includes a first surface and a second surface facing away from each other in a second direction orthogonal to the first direction,
the heat dissipation member includes a top surface facing a same side as the first surface in the second direction, and
the top surface is located between the first surface and the second surface in the second direction.

4. The semiconductor module according to claim 3, wherein the semiconductor element includes a first element and a second element,
the semiconductor device includes a first terminal electrically connected to the first element, a second terminal electrically connected to the second element, and a third terminal electrically connected to the first element and the second element, and
each of the first terminal, the second terminal, and the third terminal is exposed outside from the sealing resin.

5. The semiconductor module according to claim 4, wherein the semiconductor device includes a plurality of signal terminals,
at least one of the plurality of signal terminals is electrically connected to the semiconductor element, and
each of the plurality of signal terminals protrudes outward from the first surface.

6. The semiconductor module according to claim 5, wherein the sealing resin includes a third surface facing a same side as the first support surface in the first direction, and
each of the first terminal and the second terminal is exposed outside from the third surface.

7. The semiconductor module according to claim 6, wherein the first terminal and the second terminal are spaced apart from each other in the second direction.

8. The semiconductor module according to claim 7, wherein the first terminal includes a first connection surface protruding outward from the third surface,
the second terminal includes a second connection surface protruding outward from the third surface, and
each of the first connection surface and the second connection surface faces the same side as the first surface in the second direction.

9. The semiconductor module according to claim 5, wherein the first terminal is exposed outside from the first surface, and
the second terminal is exposed outside from the second surface.

10. The semiconductor module according to claim 9, wherein the heat dissipation member includes a first base surface facing the same side as the first support surface in the first direction,
the first base surface is located opposite to the top surface with respect to the first support surface in the second direction, and
the first base surface is farther away from the semiconductor device than is the first support surface in the first direction.

11. The semiconductor module according to of claim 4, further comprising an additional semiconductor device including the substrate, the semiconductor element, and the sealing resin, wherein
the substrate of the additional semiconductor device is exposed from the sealing resin of the additional semiconductor device,
the substrate of the additional semiconductor device is supported on the second support surface, and
the additional semiconductor device extends farther than the second support surface to a side where the top surface is located in the first direction.

12. The semiconductor module according to claim 11, wherein the heat dissipation member includes a hollow portion located inside the heat dissipation member, and
as viewed in the first direction, each of the substrate of the semiconductor device and the substrate of the additional semiconductor device overlaps with the hollow portion.

13. The semiconductor module according to claim 12, wherein the heat dissipation member includes an inlet and an outlet each of which is connected to the hollow portion, and
the inlet and the outlet are located opposite to the top surface with respect to the second surface in the second direction.

14. The semiconductor module according to claim 13, wherein the sealing resin of the semiconductor device is in contact with the first support surface, and
the sealing resin of the additional semiconductor device is in contact with the second support surface.

15. The semiconductor module according to claim 14, further comprising a spacer sandwiched between the semiconductor device and the additional semiconductor device,
wherein the spacer overlaps with the top surface as viewed in the second direction.

16. A power conversion unit comprising:
the semiconductor module as set forth in claim 13; and
a cooler, wherein
the heat dissipation member is supported on the cooler,
the cooler includes a first flow path and a second flow path each of which is located inside the cooler,
the first flow path is connected to the inlet, and
the second flow path is connected to the outlet.

17. The power conversion unit according to claim 16, further comprising a capacitor connected to the first terminal and the second terminal,
wherein the capacitor is supported on the cooler.
